(19) United States
(12) Patent Application Publication
(10) Pub. No.: US 2015/0038005 A1
(43) Pub. Date: Feb. 5, 2015

(54) JUNCTION BOX AND PHOTOVOLTAIC MODULE COMPRISING THE SAME

(71) Applicant: SAMSUNG SDI CO., LTD., Yongin-si (KR)

(72) Inventor: Yang-Geun Ji, Yongin-si (KR)

(73) Assignee: SAMSUNG SDI CO., LTD., Yongin-si (KR)

(21) Appl. No.: 14/141,354

(22) Filed: Dec. 26, 2013

Related U.S. Application Data
(60) Provisional application No. 61/862,392, filed on Aug. 5, 2013.

(51) Int. Cl. H01L 31/048

(52) U.S. Cl. CPC H01L 31/0485
USPC 439/527

(57) ABSTRACT

A junction box for a photovoltaic module includes: a housing; and a first conductive connection member coupled to the housing and including a first end portion and a second end portion separated by a gap and configured to extend outside the housing when the first conductive connection member is in a first position, and the first end portion and the second end portion being configured to overlap in the housing when the first conductive connection member is in a second position.

### CROSS-REFERENCE TO RELATED APPLICATION

This application claims priority to and the benefit of U.S. Provisional Application No. 61/862,392, filed on Aug. 5, 2013 in the U.S. Patent and Trademark Office, the entire content of which is incorporated herein by reference.

### BACKGROUND

1. Field

Embodiments of the present invention relate to a junction box and a photovoltaic module comprising the same.

2. Description of Related Art

Solar cells are apparatus for directly converting light energy into electric energy by using a photovoltaic effect and attract attention as next generation cells. Solar cells are classified as silicon solar cells, thin film solar cells, dye sensitized solar cells, and organic polymer solar cells according to their forming materials.

Meanwhile, photovoltaic modules are referred to as solar cells when coupled in series or parallel to each other. Photovoltaic modules may include a junction box for collecting electricity generated by solar cells and for preventing a current from flowing backward. In general, the junction box may include a diode for preventing the current from flowing backward and may be attached to one side surface of a photovoltaic module.

### SUMMARY

Embodiments of the present invention provide a junction box configured to be relatively easily, quickly, and reliably secured to a junction box, and a junction box including the same.

According to an embodiment of the present invention, a junction box for a photovoltaic module includes a housing; and a first conductive connection member coupled to the housing and including a first end portion and a second end portion separated by a gap and configured to extend outside the housing when the first conductive connection member is in a first position, and the first end portion and the second end portion being configured to overlap in the housing when the first conductive connection member is in a second position.

The junction box may be configured to receive a conductive wire through the gap between the first end portion and the second end portion when the first conductive member is in the first position.

At least one of the first end portion and the second end portion may further include an adhesion material.

The adhesion material may be electrically conductive.

The first conductive connection member may further include a connecting member perpendicular to the first and second end portions, wherein the connecting member has a guide groove, and wherein the housing includes a side wall and a protrusion extending from an internal surface of the side wall that is configured to engage the guide groove of the connecting member of the first conductive connection member.

The guide groove may be a first guide groove having a depth that decreases in a direction toward the first and second end portions of the first conductive connection member such that the protrusion is configured to apply a force against the connecting member of the first conductive connection member when the first conductive connection member is moved from the first position to the second position.

The guide groove may be a second guide groove that is perpendicular to the second end portion to stabilize the first conductive connection member in the housing.

The connecting member of the first conductive connection member may further include a coupling groove and the protrusion may be configured to engage the coupling groove when the first conductive connection member is in the second position.

The junction box may further include a second conductive connection member coupled to the housing and electrically coupled to the first conductive connection member.

The junction box may further include a barrier partitioning an internal space of the housing, wherein the first and second conductive connection members are configured to be in a first portion of the internal space.

The junction box may further include a diode electrically coupled between the first conductive connection member and the second conductive connection member.

The diode may be positioned at an opposite side of the barrier from the first conductive connection member in a second portion of the internal space.

The junction box may further include a cable electrically coupled to the first conductive connection member and extending outside of the housing; and a lead plate coupled between the first conductive connection member and the cable.

The lead plate may be adapted to elastically change shape.

The junction box may further include a pressure protrusion extending from an upper surface of the housing and passing through an opening in an upper surface of the first conductive connection member, wherein the pressure protrusion is configured to apply a pressure against the first and second end portions of the first conductive connection member in the second position.

The housing may further include a side wall; and a flange around a periphery of the side wall.

The flange may extend substantially perpendicularly from a lower end of the side wall.

An adhesion material may be formed on the flange and may be configured to attach the junction box to an external substrate.

A photovoltaic module may include: a substrate; a plurality of solar cells on the substrate; and the junction box, wherein the junction box is attached to the substrate in the second position.

### BRIEF DESCRIPTION OF THE DRAWINGS

FIG. 1 is a schematic exploded perspective view of a photovoltaic module according to an embodiment of the present invention.

FIG. 2A is an exploded perspective view of a photovoltaic module before a junction box is attached thereto.

FIG. 2B is an exploded perspective view of a photovoltaic module after a junction box is attached thereto.

FIG. 3 is a bottom perspective view of a junction box according to an embodiment of the present invention.

FIG. 4 is a bottom perspective view of a housing of a junction box.

FIG. 5 is a top perspective view of conductive connection members of a junction box.

FIG. 6 is a bottom view of the junction box of FIG. 3.

FIG. 7A is a lateral cross-sectional view of a junction box before being attached to a substrate.

FIG. 7B is a lateral cross-sectional view of a junction box after attached to a substrate.

### DETAILED DESCRIPTION

The present invention can apply various transformations and can have various embodiments, so specific embodiments are illustrated in the drawings, and are explained in some detail in the detailed description. However, it is not intended to limit the present invention to certain embodiments, but it should be understood to include all changes, equivalents and substitutes in the spirit and scope of the present invention. Described in the present invention, if it is determined that the gist of the present invention can be confused with a detailed description of related art, the detailed description thereof will be omitted. The terms of 1st, 2nd, etc., are used to describe various components, but components should not be limited by the terms. The terms are only used to distinguish one component from the other components. The terminology used in the present invention has been used for describing particular embodiments only, and are not intended to limit the present invention. Singular expression includes the expression of the plural, unless the context clearly indicates otherwise. In the present application, the term of “including” or “having” must be understood not to preclude one or more other features, numbers, steps, operations, elements, or components, which are described in the specification, or existence of a combination of these things or the additional possibility, but to specify the presence of such features, numbers, steps, operations, elements, components, or any combination of them. On the other hand, to use of “I” may be interpreted as “and” and may be interpreted as “or” on a case-by-case basis.

In the drawings, the dimensions of layers and regions may be exaggerated for clarity. Like reference numerals refer to the like elements throughout. It will also be understood that when a layer, film, region, or substrate is referred to as being “on” another layer, film, region, or substrate, it can be directly on the other layer, film, region, or substrate, or intervening layers may also be present.

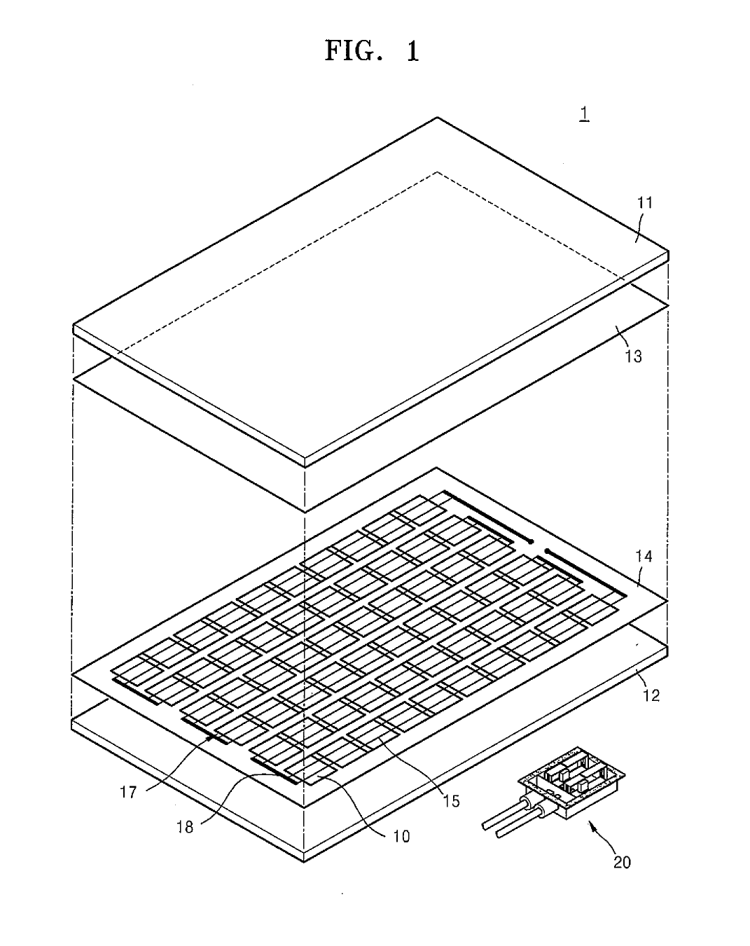

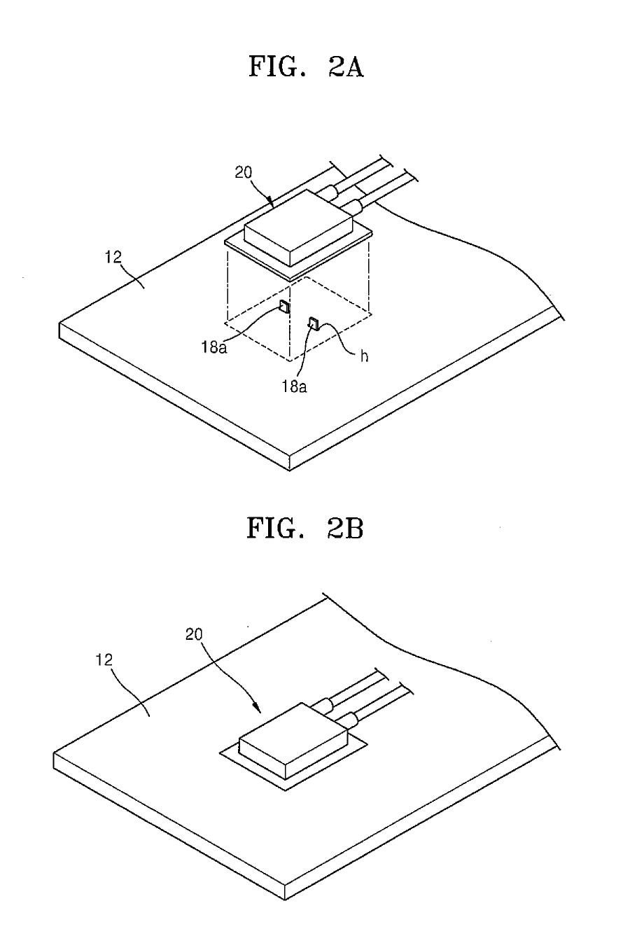

FIG. 1 is a schematic exploded perspective view of a photovoltaic module 1 according to an embodiment of the present invention. FIG. 2A is an exploded perspective view of the photovoltaic module 1 before a junction box 20 is attached thereto. FIG. 2B is an exploded perspective view of the photovoltaic module 1 after the junction box 20 is attached thereto. For convenience of explanation, FIGS. 2A and 2B show a second substrate 12 of the photovoltaic module 1 facing upward.

Referring to FIG. 1, the photovoltaic module 1 according to an embodiment of the present invention may include a plurality of solar cells 10, ribbons 15 configured to electrically couple the plurality of solar cells 10 and constitute a solar cell string 17, a first sealing film 13 and a first substrate 11 positioned on the solar cell string 17, a second sealing film 14 and a second substrate 12 positioned below the solar cell string 17, and the junction box 20 attached to the second substrate 12.

The solar cells 10, which are semiconductor devices for converting solar energy into electric energy may be, for example, silicon solar cells including a first conductive type silicon substrate, a second conductive type semiconductor layer formed on the first conductive silicon substrate and having an opposite conductive type to the first conductive silicon substrate, an anti-reflective layer including at least one opening exposing a partial surface of the second conductive type semiconductor layer and formed on the second conductive type semiconductor layer, a front surface electrode contacting the partial surface of the second conductive type semiconductor layer exposed through the at least one opening, and a rear surface electrode formed on a rear surface of the first conductive type silicon substrate. However, the present invention is not limited thereto. The solar cells 10 may be compound semiconductor solar cells, tandem solar cells, and the like.

The first substrate 11 may be a light-receiving (e.g., transparent or translucent) surface substrate and may be formed of glass having excellent light transparency or a polymer material, The first substrate 11 may have a sufficient rigidity so as to protect the solar cells 10 from being damaged due to an external shock. For example, the first substrate 11 may be formed of tempered glass. The first substrate 11 may also be formed of low iron tempered glass to prevent reflection of solar light and increase transparency of the solar light.

The second substrate 12 is positioned to face the first substrate 11 and have waterproof, insulation, and ultraviolet (UV) rays blocking functions so as to protect the solar cells 10. The second substrate 12 may be formed by stacking polyvinyl fluoride/PET/polyvinyl fluoride layers but is not limited thereto.

The first sealing film 13 is positioned between the solar cells 10 and the first substrate 11. The second sealing film 14 is positioned between the solar cells 10 and the second substrate 12. The first and second sealing films 13 and 14 are bonded by lamination to prevent moisture or oxygen from penetrating into the solar cells 10. The first and second sealing films 13 and 14 may include any suitable sealing film material such as ethylene-vinyl acetate (EVA) copolymer resin, polyvinyl butyral, an ethylene-vinyl acetate partial oxide, a silicon resin, an ester-based resin, an olefin-based resin, and the like.

The ribbons 15 may be used to couple the plurality of solar cells 10 in serial, in parallel, or in serial and parallel to each other. The plurality of solar cells 10 that are electrically coupled by using the ribbons 15 may constitute the solar cell string 17 that may be positioned adjacent to each other in several rows.

The ribbons 15 may be used to couple the front surface electrode formed on the light receiving surface of the solar cells 10 and the rear surface electrode formed on the opposite surface of the solar cells 10 through tabbing. Tabbing may be performed by coating a flux on one surface of the solar cells 10, placing the ribbons 15 on the solar cells 10 coated with the flux, and experiencing sintering.

Alternatively, the solar cells 10 may be coupled in series, in parallel, or in series and parallel to each other by thermal compression after attaching a conductive film (not shown) between one surface of the solar cells 10 and the ribbons 15. The conductive film (not shown) is a film formed of a suitable conductive film material such as an epoxy resin, an acrylic resin, a polyimide resin, a polycarbonate resin, or other suitable conductive material in which conductive particles formed of a conductive material having excellent conductivity such as gold, silver, nickel, and/or copper are scattered. The conductive particles come out of the film by thermal compression so that the solar cells 10 and the ribbons 15 may be electrically coupled to each other. As such, when the plurality of solar cells are coupled to each other by using the conductive film (not shown), a processing temperature may be lowered, which may prevent, substantially prevent, or reduce incidences of the solar cell string 17 being bent.

Bus ribbons 18 (or other conductive wire or cables) may be used to alternately couple opposing ends of the ribbons 15 of the solar cell string 17. A pair of the bus ribbons 18 having different polarities penetrate into or through the second substrate 12 so that the bus ribbon 18 may protrude or extend outside of the substrate 12. The bus ribbons 18 may be coupled to the junction box 20 positioned on a rear surface of the photovoltaic module 1.

The junction box 20 collects electricity generated by the plurality of solar cells 10, prevents (or substantially prevents) a current from flowing backward, and controls the current to flow forward. In one embodiment of the present invention, the junction box 20 is attached to the photovoltaic module 1 in one-touch type so that the junction box 20 may be electrically coupled to the bus ribbons 18.

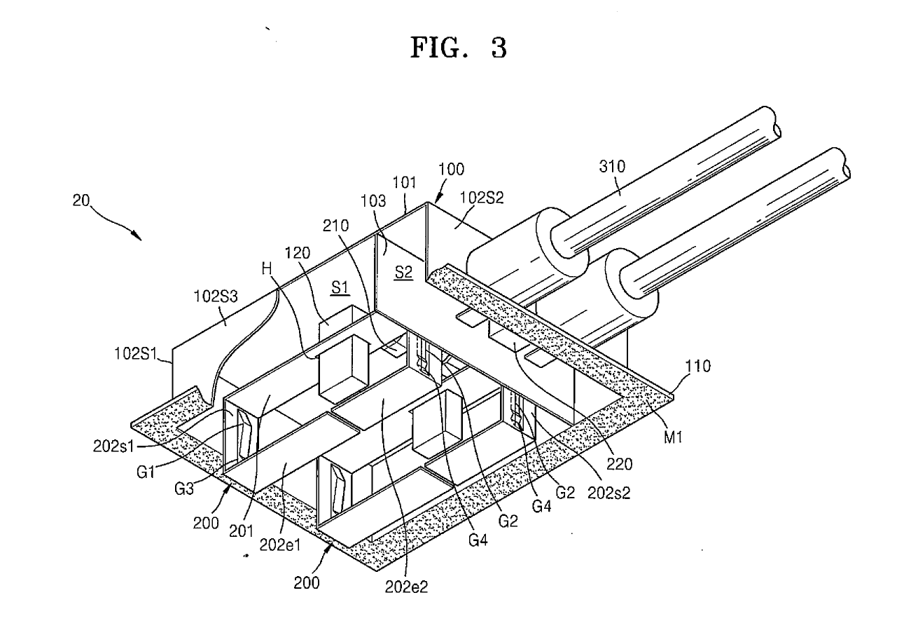

As shown in FIG. 2A, end portions 18a of the bus ribbons 18 may extend by penetrating through a rear surface of the photovoltaic module 1 that is an opposite surface of the light receiving surface, for example, holes h formed in the second substrate 12. Thereafter, an extension portion (or flange) 110 of the junction box 20 may be attached to the rear surface of the photovoltaic module 1. Concurrently, the end portions 18a of the bus ribbons 18 may contact conductive connection members 200 (shown, e.g., in FIG. 3) formed inside the junction box 20 and thus be electrically coupled to the junction box 20.

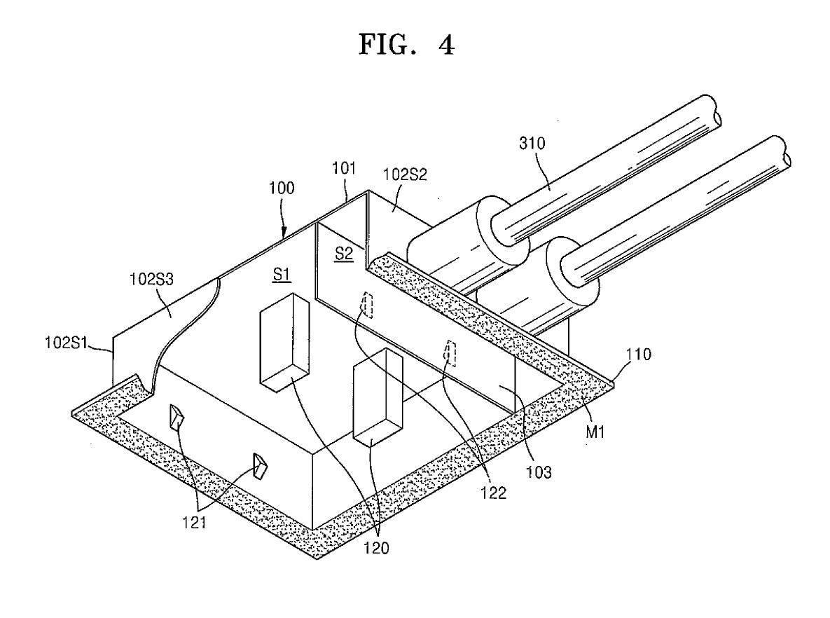

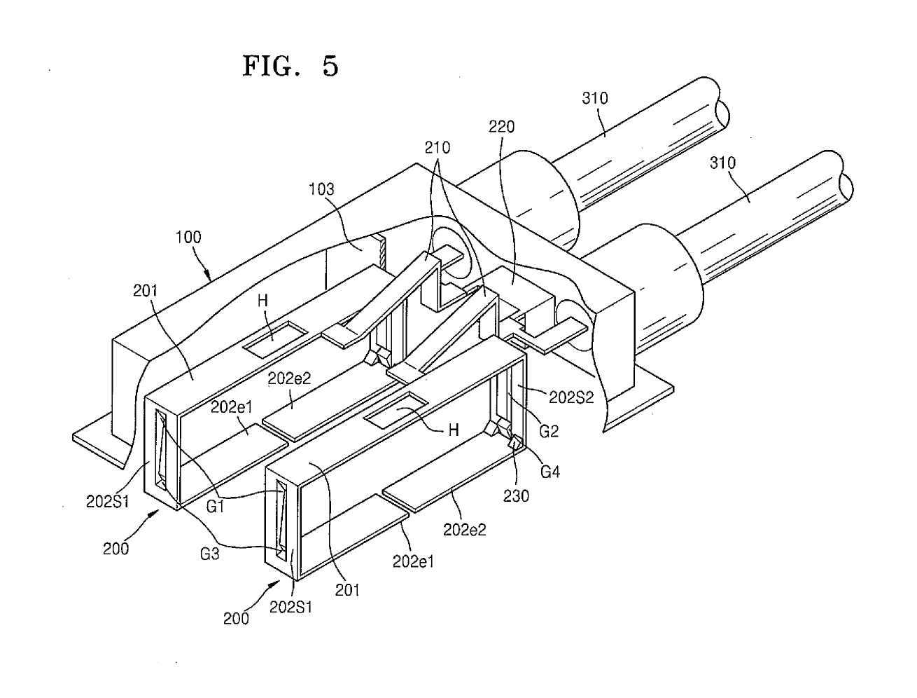

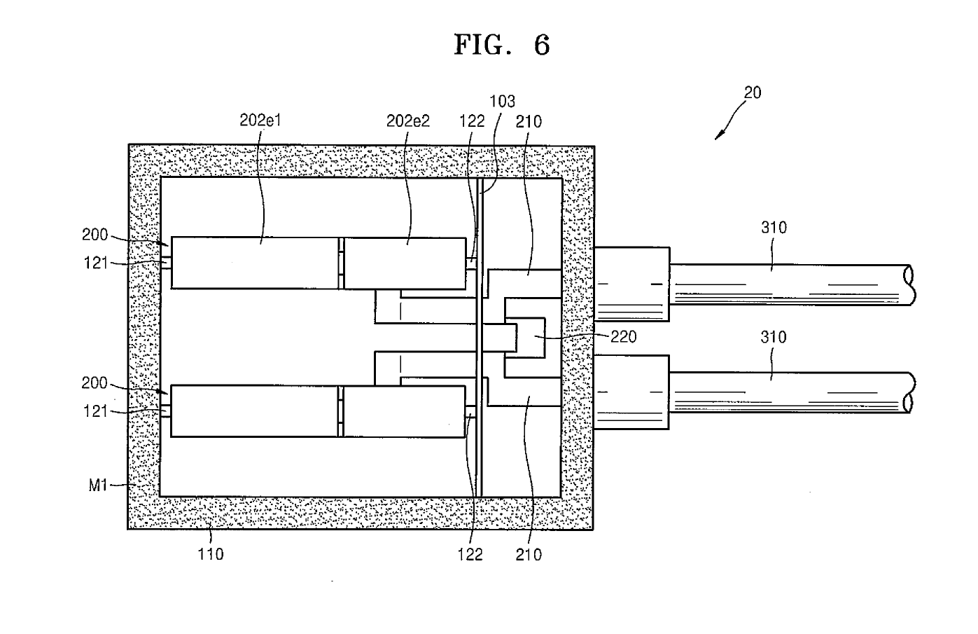

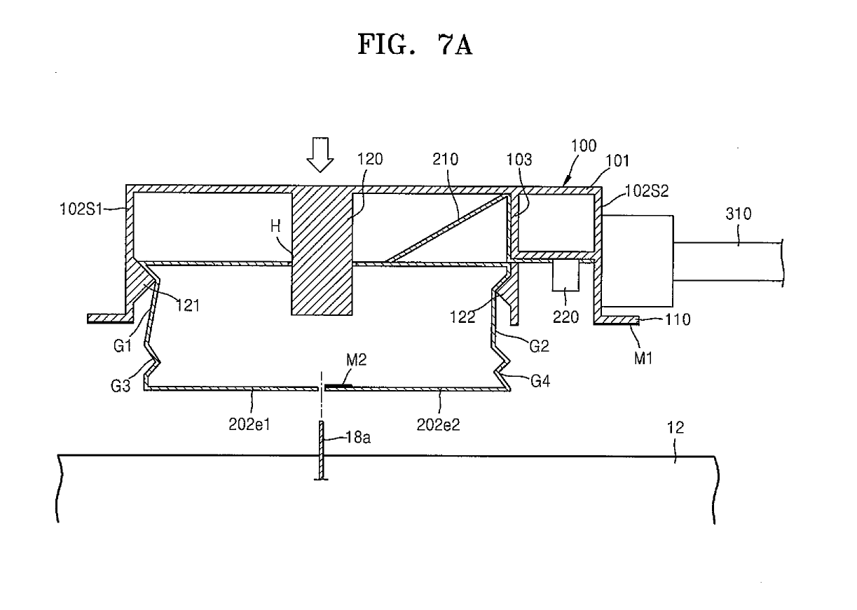

FIG. 3 is a bottom perspective view of the junction box 20 according to an embodiment of the present invention. FIG. 4 is a bottom perspective view of a housing 100 of the junction box 20. FIG. 5 is a top perspective view of the conductive connection members 200 of the junction box 20. FIG. 6 is a bottom view of the junction box 20 of FIG. 3. For convenience of explanation, a part of one side surface 102S3 of the housing 100 is opened in FIG. 3.

Referring to FIG. 3, the junction box 20 according an embodiment of the present invention may include the housing 100, the conductive connection members 200 positioned inside the housing 100, a diode 220, and a cable 310 extending outside of the housing 100. As shown in FIG. 2A, the pair of bus ribbons 18 penetrate through the second substrate 12 and protrude outside, and thus a pair of conductive connection members 200 may be provided to electrically couple the junction box 20 to the bus ribbons 18. A structure and a construction of each of the conductive connection members 200 may be the same.

Referring to FIGS. 3 and 4, the housing 100 may have an approximately hexahedral shape (although the shape of the housing 100 may vary according to the design and function of the junction box 20) having an open lower side. The housing 100 includes the extension portion 110 extending along the same plane as the open one surface and approximately perpendicular from a side surface. For example, the housing 100 includes an upper surface 101, four side surfaces including 102S1, 102S2, and 102S3, (the other side surface is not labeled) approximately perpendicular to the upper surface 101, and an open lower side opposite the upper surface 101. The end portions 18a of the bus ribbons 18 may be electrically coupled to the conductive connection members 200 through the open lower side. The extension portion 110 may extend approximately perpendicular to the four side surfaces 102S1, 102S2, and 102S3, and may be arranged to surround the open lower side and extend along the same plane as the open lower side.

The housing 100 may be attached or secured to the second substrate 12 through the extension portion 110. In this regard, the lower surface of the extension portion 110 may be attached or adhered onto the second substrate 12. A first adhesion material M1 may be formed or deposited on the lower surface of the extension portion 110. The first adhesion material M1 may use a viscosity gel adhesive or a solid adhesive tape but is not limited thereto.

An inner space of the housing 100 may be divided by a barrier rib 103. As shown in FIG. 4, pressure projections 120 extending downward from the upper surface 101 of the housing 100, and first and second projections 121 and 122 respectively formed in the side surfaces 102S1 and 102S2 facing each other may be positioned in a first space S1 of the housing 100 formed in one side of the barrier rib 101. A diode 220 (shown, e.g., in FIG. 3) electrically coupled to the conductive connection member 200 may be positioned in a second space S2 of the housing 100, which is located at the opposite side of the barrier rib 103 relative to the first space S1.

The pressure projections 120 extend downward through holes H formed in the upper surface 201 of the conductive connection member 200. The first and second projections 121 and 122 are respectively formed in the side surfaces 102S1 and 102S2 facing each other to hold the conductive connection member 200 so that the conductive connection member 200 does not fall down or become separated from the junction box 20 before the junction box 20 is attached onto the second substrate 12.

Furthermore, the first projections 121 function to push against or apply pressure to one side of the conductive connection member 200 so that the bus ribbons 18 and the conductive connection member 200 may contact each other when the junction box 20 is attached onto the second substrate 12.

Referring to FIGS. 3 and 5, the conductive connection member 200 electrically couples the end portions 18a of the bus ribbons 18 described with reference to FIGS. 2A and 2B and the cable 310 extending outside of the housing 100. Before the junction box 20 is attached onto the second substrate 12, the conductive connection member 200 is partially accommodated in the housing 100. After the junction box 20 is attached onto the second substrate 12, the conductive connection member 200 is wholly accommodated in the housing 100, and the end portions 18a of the bus ribbons 18 and the conductive connection member 200 are electrically coupled.

The conductive connection member 200 may include the upper surface 201 having a hole H to allow the pressure projections 120 to pass therethrough, a first side surface 202S1 and a second side surface 202S2 approximately perpendicular to the upper surface 201 and facing each other, a first end portion 202e1 extending approximately perpendicular to the first side surface 202S1, and a second end portion 202e2 extending approximately perpendicular to the second side surface 202S2, and lead plates 210 for mechanically and electrically coupling the conductive connection member 200 to the cable 310.

The first end portion 202e1 and the second end portion 202e2 may be located on the same plane and spaced apart from each other by a gap therebetween. The end portions 18a of the bus ribbons 18 may extend toward the gap between the first end portion 202e1 and the second end portion 202e2, may overlap each other between the first end portion 202e1 and the second end portion 202e2, and may be electrically coupled to the conductive connection member 200. The lead plates 210 may pass through the barrier rib 103 of the housing 100 so as to extend toward the second space S2, and may be coupled to the cable 310.

The first side surface 202S1 of the conductive connection member 200 may be positioned to face the side surface 102S1 of the housing 100 in which the first projections 121 are formed. The second side surface 202S2 of the conductive connection member 200 may be positioned to face the other side surface 102S2 of the housing 100 in which the second projections 122 are formed.

The first side surface 202S1 of the conductive connection member 200 may include a first guide groove G1 and a first seating or coupling groove G3 located below the first guide groove G1. The second side surface 202S2 of the conductive connection member 200 may include a second guide groove G2 and a second seating or coupling groove G4 located below the second guide groove G2. Before the junction box 20 is attached onto the second substrate 12, at least a part of the first and second projections 121 and 122 may be accommodated in the first guide groove G1 and the second guide groove G2 respectively, and thus the conductive connection member 200 may be partially accommodated in the housing 100.

When the junction box 20 is attached onto the second substrate 12, the conductive connection member 200 that is partially accommodated in the housing 100 relatively moves toward the upper surface 101 of the housing 100 so that the conductive connection member 200 may be wholly accommodated in the housing 100. In this regard, the first projections 121 of the housing 100 move along the first guide groove G1 and are accommodated in the first seating groove G3, and the second projections 122 of the housing 100 move along the second guide groove G2 and are accommodated in the second seating groove G4.

A depth of the first guide groove G1 and a depth of the first seating groove G3 may be different from depths of the first projections 121. For example, the depth of the first guide groove G1 and the depth of the first seating groove G3 may be lower than the projection-heights of the first projections 121. The first guide groove G1 may have an inclined surface or depth (e.g., internal angle or shape) such that the depth of the first guide groove G1 may be reduced in a downward direction with respect to the upper surface 101 of the housing 100. Thus, when the conductive connection member 200 moves into the housing 100, the first projections 121 apply pressure against the first side surface 202S1 and tend to move the first end portion 202e1 toward the second end portion 202e2. For example, when the first projections 121 are accommodated in the first seating groove G3 through the first guide groove G1, the first side surface 202S1 is pushed toward the second side surface 202S2 by the first projections 121, and the first end portion 202e1 coupled to the first side surface 202S1 moves toward the second end portion 202e2.

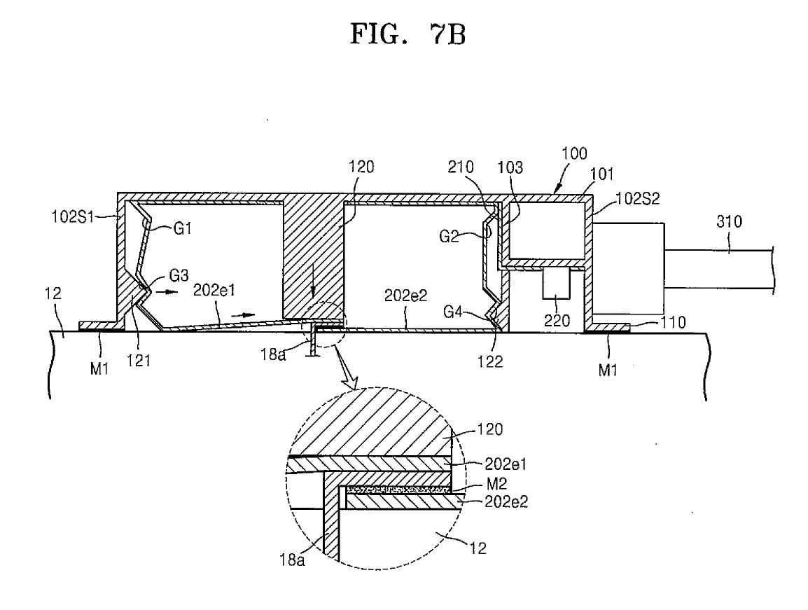

In this regard, the end portions 18a of the bus ribbons 19 may extend perpendicularly with respect to the first and second end portions 202e1 and 202e2 into the gap between the first end portion 202e1 and the second end portion 202e2, as shown, for example, in FIG. 7A. As the first side surface 202S1 is pushed toward the second side surface 202S2, the end portions 18a of the bus ribbons 19 may be bent or folded, such that the first and second end portions 202e1 and 202e2 overlap each other, with a portion of each of the end portions 18a being positioned between the first end portion 202e1 and the second end portion 202e2, as shown, for example, in FIG. 7B.

As described above, when the conductive connection member 200 moves into the housing 100, although the first end portion 202e1 move toward the second end portion 202e2 because of a force from the first projections 121, the second end portion 202e2 does not move toward the first end portion 202e1 as the conductive connection member 200 moves upward. That is, the second side surface 202S2 and the second end portion 202e2 of the conductive connection member 200 may be perpendicular to each other.

To this end, the second guide groove G2 and the second seating groove G4 may be formed such that the second projections 122 may not push against the second side surface 202S2 toward the first side surface 202S1 or move the second end portion 202e2 as the conductive connection member 200 moves upward. For example, a maximum depth of the second guide groove G2 and a maximum depth of the second seating groove G4 may be substantially the same as projection-heights of the second projections 122. Additionally, the inside depth of the second guide groove G2 may be parallel to the second side surface 202S2, unlike the first guide groove G1.

Returning to FIG. 5, the conductive connection member 200 may further include an angle maintaining member 230 for maintaining an angle between the second side surface 202S2 and the second end portion 202e2. The angle maintaining member 230 operates such that when a force, other than an external force of the second projections 122 for attaching the junction box 20, is applied, the angle between the second side surface 202S2 and the second end portion 202e2 may have a uniform value. That is, the angle maintaining member 230 operates to maintain a uniform angle between the second side surface 202S2 and the second end portion 202e2.

As shown in FIGS. 5 and 6, the lead plates 210 may extend from the upper surface 201 of the conductive connection member 200 to the cable 310. The lead plates 210 may pass through the barrier rib 103 located between the first and second spaces S1 and S2. One side of the lead plates 210 in the first space S1, which is coupled to the upper surface 201 of the conductive connection member 200, may include an inclined surface bent to have an angle (e.g., a predetermined angle such as an acute angle) as shown in FIG. 5. The inclined surface of the lead plates 210 may be elastic. Thus, when the junction box 20 is attached onto the second substrate 12, and the conductive connection member 200 relatively moves upward, the inclined surface of the lead plates 210 may become flat (e.g., relatively parallel with respect to the upper surface 101 of the housing) and contact an inner side of the upper surface 101 of the housing 100.

The diode 220 may be located in the second space S2 of the housing 100 and may be electrically coupled to the conductive connection member 200. For example, the diode 220 may be electrically coupled to the lead plates 210 extending in the second space S2. The diode 220 prevents a current through in the cable 310 from flowing backward, and controls the current to flow forward.

An attachment of the junction box 20 and an electrical connection of the bus ribbons 18 and the junction box 20 will now be described in more detail below.

FIG. 7A is a lateral cross-sectional view of the junction box 20 before being attached to the second substrate 12. FIG. 7B is a lateral cross-sectional view of the junction box 20 after being attached to the second substrate 12.

Referring to FIG. 7A, the pressure projections 120 extend downward through the holes H formed in the upper surface 201 of the conductive connection member 200. A gap between the first end portion 202e1 and the second end portion 202e2 of the conductive connection member 200 is located below the pressure projections 120. The end portions 18a of the bus ribbons 18 protrude through the gap. That is, the pressure projections 120 may be positioned at a location corresponding to or overlapping the gap, for example, above the gap.

At least a part of the first projections 121 formed in the first side surface 202S1 of the housing 100 is accommodated in the first guide groove G1, and at least a part of the second projections 122 formed in the second side surface 202S2 is accommodated in the second guide grove G2, so that the conductive connection member 200 is partially accommodated (e.g., stabilized or secured) in the housing 100 by the first and second projections 121 and 122 positioned at opposing sides or ends thereof.

As described above, the lead plates 210 extend through the barrier rib 103 to couple the upper surface 201 of the conductive connection member 200 and the cable 310. One side of the lead plates 210 adjacent to the upper surface 201 of the conductive connection member 200 may include an inclined surface, and another side of the lead plates 210 adjacent to the cable 310 may be coupled to the cable 310 through the barrier rib 103.

The first adhesion material M1 may be formed on one side surface of the extension portion 110 of the housing 100, i.e., a surface facing toward an upper surface of the second substrate 12.

A second adhesion material M2 may be formed or deposited on the second end portion 202e2 at a portion of the second end portion 202e2 that is adjacent to the gap between the first end portion 202e1 and the second end portion 202e2. Additionally, the second adhesion material M2 may be formed on a surface of the second end portion 202e2 facing away from an upper surface of the second substrate 12. The second adhesion material M2 formed on the second end portion 202e2 may be a conductive adhesion material for electrically coupling the end portions 18a of the bus ribbons 18 to the conductive connection member 200.

Referring to FIG. 7B, when the junction box 20 is provided on the second substrate 12, one side surface of the extension portion 110 (e.g., a lower surface) contacts the second substrate 12, and the junction box 20 is attached or secured onto the second substrate 12 by using the first adhesion material M1 formed or deposited between the extension portion 110 and the second substrate 12. Concurrently with the attachment of the junction box 20 onto the second substrate 12, the end portions 18a of the bus ribbons 18 positioned in the gap are bent such that the end portions 18a are positioned between overlapping ends of the first end portion 202e1 and the second end portion 202e2. Accordingly, the end portions 18a of the bus ribbons 18 are electrically coupled to the conductive connection member 200 through the first end portion 202e1 and the second end portion 202e2.

A process of electrically coupling the bus ribbons 18 and the conductive connection member 200 is as follows.

When the junction box 20 is attached or secured onto the second substrate 12, the conductive connection member 200 is positioned between the second substrate 12 and the housing 100 and is moved relatively into the housing 100. In this regard, the first projections 121 formed in one side surface of the housing 100 are accommodated in the first seating groove G3 through the first guide groove G1, and the second projections 122 formed in another side surface of the housing 100 are accommodated in the second seating groove G4 through the second guide groove G2.

A depth of the second guide groove G2 and a depth of the second seating groove G4 are substantially the same as projection-heights of the second projections 122 and thus the second side surface 20282 of the conductive connection member 200 and the second end portion 202e2 extending approximately perpendicular to the second side surface 20282 are accommodated in the housing 100.

However, a depth of the first guide groove G1 and a depth of the first seating groove G3 are lower than projection-heights of the first projections 121, and the depth of the first guide groove G1 decreases away from the upper surface 101 of the housing 100, such that the first guide groove G1 may have an inclined or angled surface or depth, and thus according to the relative movement of the conductive connection member 200, the first side surface 202S1 is pushed toward the second side surface 202S2, and the first end portion 202e1 coupled to the first side surface 202S1 moves toward the second end portion 202e2.

The end portions 18a of the bus ribbons 18 are bent to be positioned on the second end portion 202e2 by the first end portion 202e1 that moves toward the second end portion 202e2, because the first end portion 202e1 is pushed by the first projections 121. In this regard, as the pressure projections 120 are pressing an overlapping region between the first end portion 202e1 and the second end portion 202e2, the end portions 18a of the bus ribbons 18 may contact the first end portion 202e1 and the second end portion 202e2 while being positioned between the second end portion 202e2 and the first end portion 202e1. The end portions 18a of the bus ribbons 18 may be more securely and/or reliably adhered and electrically coupled to the second end portion 202e2 through the second adhesion material M2 formed or deposited on the second end portion 202e2.

As described above, the junction box 20 may be electrically coupled to the bus ribbons 18 concurrently with the attachment of the junction box 20 onto the second substrate 12 in one-touch type, thereby creating a relatively stable electrical connection and achieving relatively excellent assembling.

It should be understood that the example embodiments described herein should be considered in a descriptive sense only and not for purposes of limitation. Descriptions of features or aspects within each embodiment should typically be considered as available for other similar features or aspects in other embodiments.

It will be recognized by those skilled in the art that various modifications may be made to the illustrated and other embodiments of the invention described above, without departing from the broad inventive step thereof. It will be understood therefore that the invention is not limited to the particular embodiments or arrangements disclosed, but is rather intended to cover any changes, adaptations or modifications which are within the scope and spirit of the invention as defined by the appended claims, and their equivalents.

<Explanation of Some of the Reference Numerals>

| 1: photovoltaic module | 10: solar cell |
|---|---|
| 11: first substrate | 12: second substrate |
| 13: first sealing film | 14: second sealing film |
| 17: solar cell string | 18: bus ribbon |
| 20: junction box | 100: housing |
| 101: upper surface of housing | |
| 102S1, 102S2, 102S3: side surfaces of housing | |
| 103: barrier rib | 110: extension portion |
| 120: pressure projections | 121: first projections |
| 122: second projections | 200: conductive connection member |
| 201: upper surface of conductive connection member | |
| 202S1: first side surface of conductive connection member | |
| 202S2: second side surface of conductive connection member | |
| 202e1: first end portion of conductive connection member | |
| 202e2: second end portion of conductive connection member | |
| 210: lead plates | 22: diode |
| 310: cable | S1: first space |
| S2: second space | G1: first guide groove |
| G2: second guide groove | G3: first seating groove |
| G4: second seating groove | |

What is claimed is:

1. A junction box for a photovoltaic module, the junction box comprising:
a housing; and
a first conductive connection member coupled to the housing and comprising
a first end portion and a second end portion separated by a gap and configured to extend outside the housing when the first conductive connection member is in a first position, and
the first end portion and the second end portion being configured to overlap in the housing when the first conductive connection member is in a second position.

2. The junction box of claim 1, wherein the junction box is configured to receive a conductive wire through the gap between the first end portion and the second end portion when the first conductive member is in the first position.

3. The junction box of claim 1, wherein at least one of the first end portion and the second end portion further comprise an adhesion material.

4. The junction box of claim 3, wherein the adhesion material is electrically conductive.

5. The junction box of claim 1, wherein the first conductive connection member further comprises a connecting member perpendicular to the first and second end portions, wherein the connecting member has a guide groove, and
wherein the housing comprises a side wall and a protrusion extending from an internal surface of the side wall that is configured to engage the guide groove of the connecting member of the first conductive connection member.

6. The junction box of claim 5, wherein the guide groove is a first guide groove having a depth that decreases in a direction toward the first and second end portions of the first conductive connection member such that the protrusion is configured to apply a force against the connecting member of the first conductive connection member when the first conductive connection member is moved from the first position to the second position.

7. The junction box of claim 5, wherein the guide groove is a second guide groove that is perpendicular to the second end portion to stabilize the first conductive connection member in the housing.

8. The junction box of claim 5, wherein the connecting member of the first conductive connection member further comprises a coupling groove and the protrusion is configured to engage the coupling groove when the first conductive connection member is in the second position.

9. The junction box of claim 1, further comprising:
a second conductive connection member coupled to the housing and electrically coupled to the first conductive connection member.

10. The junction box of claim 9, further comprising a barrier partitioning an internal space of the housing, wherein the first and second conductive connection members are configured to be in a first portion of the internal space.

11. The junction box of claim 10, further comprising a diode electrically coupled between the first conductive connection member and the second conductive connection member.

12. The junction box of claim 11, wherein the diode is positioned at an opposite side of the barrier from the first conductive connection member in a second portion of the internal space.

13. The junction box of claim 1, further comprising:
a cable electrically coupled to the first conductive connection member and extending outside of the housing; and
a lead plate coupled between the first conductive connection member and the cable.

14. The junction box of claim 13, wherein the lead plate is adapted to elastically change shape.

15. The junction box of claim 1, further comprising:
a pressure protrusion extending from an upper surface of the housing and passing through an opening in an upper surface of the first conductive connection member, wherein the pressure protrusion is configured to apply a pressure against the first and second end portions of the first conductive connection member in the second position.

16. The junction box of claim 1, wherein the housing further comprises:
a side wall; and
a flange around a periphery of the side wall.

17. The junction box of claim 16, wherein the flange extends substantially perpendicularly from a lower end of the side wall.

18. The junction box of claim 17, further comprising an adhesion material formed on the flange configured to attach the junction box to an external substrate.

19. A photovoltaic module comprising:
a substrate;
a plurality of solar cells on the substrate; and
the junction box of claim 1, wherein the junction box is attached to the substrate in the second position.
